(19) United States
(12) Patent Application Publication
(10) Pub. No.: US 2024/0396545 A1
(43) Pub. Date: Nov. 28, 2024

(54) DRIVE CIRCUIT, ARRAY CIRCUIT, AND NEUROMORPHIC DEVICE

(71) Applicant: TDK CORPORATION, Tokyo (JP)

(72) Inventors: Yuji KAKINUMA, Tokyo (JP); Tatsuo SHIBATA, Tokyo (JP)

(73) Assignee: TDK CORPORATION, Tokyo (JP)

(21) Appl. No.: 18/572,341

(22) PCT Filed: Jun. 21, 2021
(86) PCT No.: PCT/JP2021/023320

§ 371 Date: Apr. 22, 2024

(51) Int. Cl. H03K 17/56

(52) U.S. Cl. CPC H03K 17/56

(57) ABSTRACT

A drive circuit including: a load resistor; a variable resistance element configured to have at least a first terminal and a second terminal and be capable of changing a resistance value; and a constant current source configured to determine a magnitude of a current flowing through the load resistor based on an input voltage and a resistance value of the variable resistance element, in which a voltage across the load resistor is output as an output voltage.

### TECHNICAL FIELD

The present invention relates to a drive circuit, an array circuit, and a neuromorphic device.

### BACKGROUND ART

Neuromorphic devices performing arithmetic operations using a neural network have been researched and developed.

Relating to this, methods for performing arithmetic operations using a neural network by using variable resistance elements of which resistance values change in accordance with magnetoresistance effects such as a giant magnetoresistance effect, a tunnel magnetoresistance effect, and the like are known (see Patent Document 1).

### CITATION LIST

### Patent Document

### [Patent Document 1]

PCT Publication No. 2017/183573

### SUMMARY OF INVENTION

### Technical Problem

In an arithmetic operation using a neural network, a resistance value of a variable resistance element is used as a weight, and a current generated in accordance with an input pulse signal passing through the variable resistance element is output as a result of a product operation. In other words, in such a product operation, the magnitude of this current changes in accordance with a change of the resistance value of the variable resistance element. However, since it is difficult to widen a range in which the resistance value of the variable resistance element is changed, there are cases in which it is difficult to judge a change of the magnitude of this current according to a change of the resistance value of the variable resistance element from a change due to noise.

### Solution to Problem

One aspect of the present invention is a drive circuit including: a load resistor; a variable resistance element configured to have at least a first terminal and a second terminal and be capable of changing a resistance value based on a magnetoresistance effect; and a constant current source configured to determine a magnitude of a current flowing through the load resistor based on an input voltage and a resistance value of the variable resistance element, in which a voltage across the load resistor is output as an output voltage.

### Advantageous Effects of Invention

According to the present invention, a drive circuit, an array circuit, and a neuromorphic device capable of improving the resolution of a variable resistance element with respect to a change of the resistance value can be provided.

### BRIEF DESCRIPTION OF DRAWINGS

FIG. 1 is a diagram illustrating an example of the configuration of a drive circuit 1 according to an embodiment.

FIG. 2 is a diagram illustrating an example of the configuration of the drive circuit 1 of a case in which a bipolar transistor is used as a constant current source CP.

FIG. 3 is an equivalent circuit representing the drive circuit 1 illustrated in FIG. 2.

FIG. 4 is a diagram illustrating an example of the configuration of a drive circuit 1 including a variable resistance element MS of a three-terminal type.

FIG. 5 is a diagram illustrating one example of the configuration of an array circuit 2.

FIG. 6 is a diagram illustrating another example of the configuration of the array circuit 2.

FIG. 7 is a diagram illustrating further another example of the configuration of the array circuit 2.

FIG. 8 is a diagram illustrating an example of the configuration of a drive circuit 1B.

FIG. 9 is an image view illustrating an example of a view in which a constant current source CP and a variable resistance element MSA of a three-terminal type of the drive circuit 1A are stacked on a substrate using a top pin structure as an integrated circuit.

FIG. 10 is an image view illustrating an example of a view in which a constant current source CP and a variable resistance element MSA of a three-terminal type of the drive circuit 1A are stacked on a substrate using a bottom-top pin structure as an integrated circuit.

### DESCRIPTION OF EMBODIMENTS

### Embodiment

Hereinafter, an embodiment of the present invention will be described with reference to the drawings. In this embodiment, a conductor transmitting an electric signal will be described as a transmission line. The transmission line, for example, may be a conductor printed on a substrate or may be a conductive wire such as a conductor or the like formed in a linear shape or the like. In addition, in this embodiment, a voltage represents an electric potential difference from a predetermined reference electric potential, and illustration and description of the reference electric potential will be omitted. Here, the reference electric potential may be any electric potential. Hereinafter, as one example, a case in which the reference electric potential is the ground electric potential will be described. In addition, in this embodiment, a voltage across a member having a certain resistance value represents an electric potential difference generated between both ends of this member and does not necessarily represent an electric potential difference from the ground electric potential.

### <Configuration of Drive Circuit>

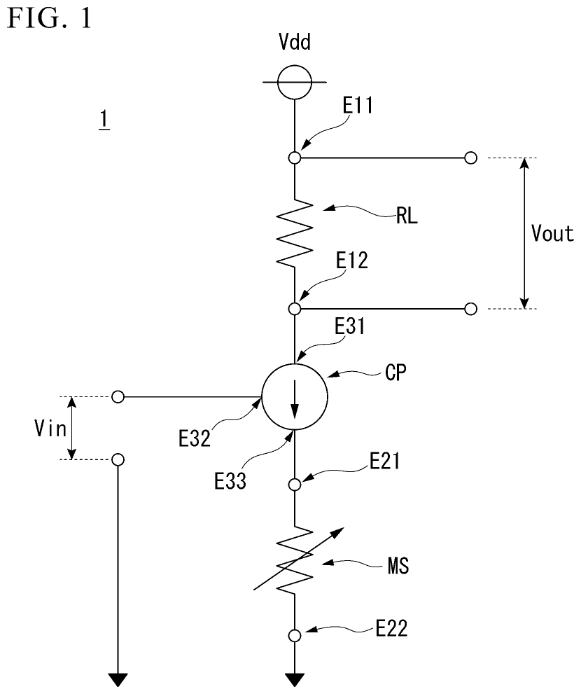

FIG. 1 is a diagram illustrating an example of the configuration of a drive circuit 1 according to an embodiment.

The drive circuit 1 is a circuit that is driven by inputting an input voltage Vin to an input terminal and outputs an output voltage Vout. The drive circuit 1, for example, is used as an analog circuit that performs a product operation in a neural network. In addition, the drive circuit 1 may be used as a circuit that achieves other goals.

The drive circuit 1 includes a load resistor RL, a variable resistance element MS, and a constant current source CP. The drive circuit 1 outputs a voltage across the load resistor RL as an output voltage Vout.

First, a connection form of the load resistor RL, the variable resistance element MS, and the constant current source CP in the drive circuit 1 will be described.

The load resistor RL has two terminals including a terminal E11 and a terminal E12.

The variable resistance element MS has two terminals including a terminal E21 and a terminal E22.

The constant current source CP has three terminals including a terminal E31, a terminal E32, and a terminal E33.

The terminal E11 of the load resistor RL is connected to a constant voltage source Vdd. The constant voltage source Vdd is a voltage source that supplies a voltage Vc of a magnitude determined in advance. In other words, the voltage Vc is applied to the terminal E11 of the load resistor RL. In addition, as long as the function of the drive circuit 1 is not impaired, another element, another member, another circuit, another device, and the like may be configured to be connected between the terminal E11 and the constant voltage source Vdd.

The terminal E12 of the load resistor RL is connected to the terminal E31 of the constant current source CP. In addition, as long as the function of the drive circuit 1 is not impaired, another element, another member, another circuit, another device, and the like may be configured to be connected between the terminal E12 and the constant current source CP.

The terminal E32 of the constant current source CP is a terminal to which an input voltage Vin is input. For this reason, an external circuit, an external device, and the like that can supply the input voltage Vin to the terminal E32 are connected to the terminal E32. In FIG. 1, for simplification of the drawing, such an external circuit, external device, and the like are omitted. In addition, as long as the function of the drive circuit 1 is not impaired, another element, another member, another circuit, another device, and the like may be configured to be connected between the terminal E32 and such an external circuit, external device, and the like.

The terminal E33 of the constant current source CP is connected to the terminal E21 of the variable resistance element MS. In addition, as long as the function of the drive circuit 1 is not impaired, another element, another member, another circuit, another device, and the like may be configured to be connected between the terminal E33 and the variable resistance element MS.

The terminal E22 of the variable resistance element MS is grounded. In addition, as long as the function of the drive circuit 1 is not impaired, another element, another member, another circuit, another device, and the like may be configured to be connected between the terminal E22 and the ground.

Next, the configuration of each of the load resistor RL, the variable resistance element MS, and the constant current source CP will be described.

For example, the load resistor RL is configured using one or more resistance elements. In addition, the load resistor RL may be another member having a resistance value enabling achievement of a function as the load resistor.

A transmission line used for detecting an output voltage Vout is connected to both ends of the load resistor RL. In FIG. 1, for simplification of the drawing, an external device detecting the output voltage Vout is omitted.

The variable resistance element MS is a magnetoresistance effect element of which a resistance value changes in accordance with magnetoresistance effects such as a giant magnetoresistance effect, a tunnel magnetoresistance effect, and the like. In other words, the variable resistance element MS is an element of which a resistance value can be changed based on a magnetoresistance effect. More specifically, the variable resistance element MS, for example, is a magnetoresistance effect element of a spin transfer torque (STT) type using a spin transfer torque, a magnetoresistance effect element of a spin orbital torque type using a spin orbital torque (SOT), a magnetoresistance effect element of a magnetic domain wall motion type using movement of a magnetic domain wall in a ferromagnetic layer, or the like.

In the example illustrated in FIG. 1, the variable resistance element MS is a magnetoresistance effect element of a two-terminal type. In this case, the variable resistance element MS, for example, is a magnetoresistance effect element of the STT type and has a resistance value that changes in accordance with a flow of a spin-polarized current. In addition, the variable resistance element MS of the two-terminal type may be another magnetoresistance effect element such as a magnetoresistance effect element of which a resistance value changes in accordance with application of a magnetic field.

The constant current source CP determines the magnitude of a current flowing through the load resistor RL based on the input voltage to be input Vin and the resistance value of the variable resistance element MS. More specifically, in a case in which an input voltage Vin is applied to the terminal E32, the constant current source CP causes a current of a magnitude determined based on the input voltage Vin applied to the terminal E32 and the resistance value of the variable resistance element MS to flow through the load resistor RL. As a result, in the drive circuit 1, a voltage of a magnitude determined in accordance with the magnitude of the input voltage to be input Vin and the resistance value of the variable resistance element MS is generated as a voltage across the load resistor RL. The drive circuit 1 outputs the voltage across the load resistor RL generated in this way as an output voltage Vout. In addition, in a case in which an input voltage Vin is applied to the terminal E32, the constant current source CP causes a current acquired by combining a current flowing through the terminal E32 and a current flowing through the load resistor RL to flow through the variable resistance element MS.

The drive circuit 1 having such a configuration can detect a change of a resistance value of the variable resistance element MS as a change of the output voltage Vout. Here, a range in which the resistance value of the variable resistance element MS that is a magnetoresistance effect element changes cannot be arbitrarily widened at least using a currently known method. For this reason, when the resistance value of the variable resistance element MS is to be changed in multiple stages, a change near a first stage of the resistance value of the variable resistance element MS becomes small.

However, in the drive circuit 1, by adjusting the resistance value of the load resistor RL, a change of the output voltage Vout according to a change near the first stage of the resistance value of the variable resistance element MS can be increased. In such a situation, in the drive circuit 1, it is preferable that the resistance value of the load resistor RL be able to be selected. The resistance value of the load resistor RL being able to be selected, for example, represents that the load resistor RL is a variable resistor, a plurality of resistance elements having mutually different magnitudes of resistance values can be mounted in the drive circuit 1 as a load resistor RL, and the like. The larger the resistance value of the load resistor RL, the more the drive circuit 1 increases a change of the output voltage Vout according to a change near the first stage of the resistance value of the variable resistance element MS. In accordance with this, a user of the drive circuit 1 can easily amplify the change of the output voltage Vout according to a change near the first stage of the resistance value of the variable resistance element MS to be a desired magnitude. In other words, the drive circuit 1 can improve the resolution for changes of the resistance value of the variable resistance element MS.

Here, the constant current source CP may have any configuration as long as it is a configuration in which the magnitude of a current flowing through the load resistor RL can be determined based on an input voltage Vin and a resistance value of the variable resistance element MS.

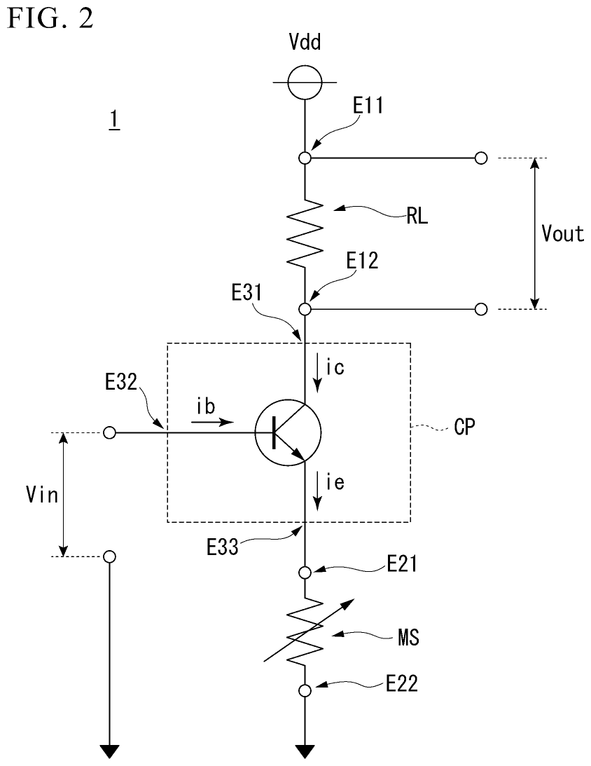

FIG. 2 is a diagram illustrating an example of the configuration of a drive circuit 1 of a case in which a bipolar transistor is used as a constant current source CP.

In the example illustrated in FIG. 2, a terminal E31 of the constant current source CP is a collector terminal of the bipolar transistor. In this example, a terminal E32 of the constant current source CP is a base terminal of the bipolar transistor. In addition, in this example, a terminal E33 of the constant current source CP is an emitter terminal of the bipolar transistor. In other words, in this example, the constant current source CP is an emitter-grounded bipolar transistor.

In the example illustrated in FIG. 2, in a case in which an input voltage Vin is applied to the terminal E32 of the constant current source CP, a base current flows through the terminal E32. As a result, a collector current flows through a load resistor RL, and an emitter current that is a current acquired by combining the base current and the collector current flows through a variable resistance element MS.

Here, the magnitude of the collector current flowing through the load resistor RL is a magnitude acquired by amplifying the magnitude of the base current flowing through the terminal E32 of the constant current source CP with an amplification factor hfe. Here, hfe is a current amplification factor. For this reason, the magnitude of the collector current does not depend on the magnitude of a voltage Vc supplied by a constant voltage source Vdd and the resistance value of the load resistor RL. This represents that the magnitude of a current flowing through the load resistor RL is determined in accordance with an input voltage Vin and a resistance value of the variable resistance element MS. From such situations, the constant current source CP illustrated in FIG. 1 can be realized using a bipolar transistor.

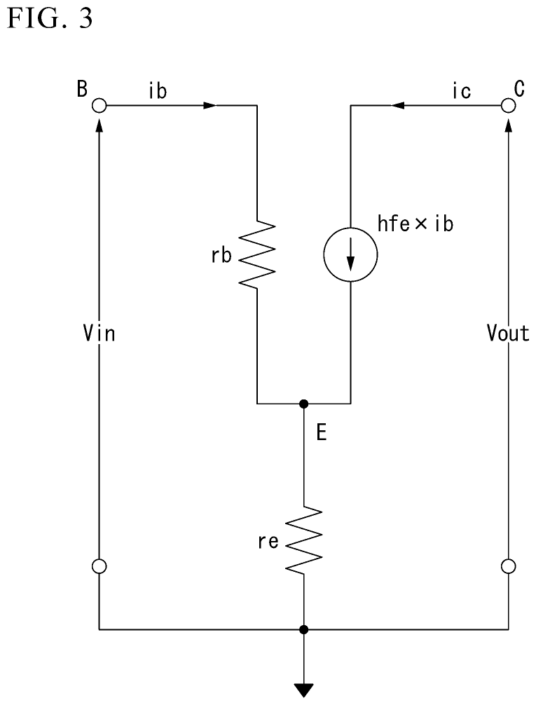

The reason for being able to realize the constant current source CP using a bipolar transistor will be described using an equivalent circuit illustrated in FIG. 3. FIG. 3 is an equivalent circuit representing the drive circuit 1 illustrated in FIG. 2. A resistor rb illustrated in FIG. 3 illustrates resistance between the base and the emitter of a bipolar transistor. A resistor re illustrated in FIG. 3 represents a resistor connected between the emitter terminal and the ground, that is, a variable resistance element MS. A constant current source illustrated in FIG. 3 represents a current source causing a collector current ic that is hfe times a base current ib to flow in a case in which the base current ib flows through the resistor rb by applying an input voltage Vin between the base and the emitter illustrated in FIG. 3.

In the equivalent circuit illustrated in FIG. 3, the emitter current ie is represented as in the following Equation (1) in accordance with a sum of the base current ib and the collector current ic.

$$ie = ib + ic \qquad ( 1 )$$

In addition, the collector current ic is represented as in the following Equation (2) in accordance with hfe that is a current amplification factor and the base current ib.

$$ic = hfe \times ib \qquad ( 2 )$$

In accordance with Equation (1) and Equation (2) described above, the following Equation (3) can be acquired.

$$ie = ib + hfe \times ib = i b ( 1 + hfe ) \qquad ( 3 )$$

On the other hand, the input voltage Vin can be represented as in the following Equation (4) using the Ohm's law.

$$V in = rb \times ib + r e \times ie = rb \times i b + r e \times i b ( 1 + hfe ) = ib ( r b + r e ( 1 + hfe ) ) \qquad ( 4 )$$

For this reason, the collector current ic is represented as in the following

### Equation (5).

$$ic = hfe \times ib = hfe \times ( V in / ( rb + r e \times ( 1 + hfe ) ) ) \qquad ( 5 )$$

Here, when a bipolar transistor of hfe=about 150 is used as the constant current source CP, (1+hfe)˜hfe. In addition, it is known that, when the voltage between the base and the emitter is 0.75 V or more, the resistance rb between the base and the emitter rapidly decreases. For this reason, in Equation (5) described above, rb can be ignored. From description presented above, Equation (5) described above can be approximated as in the following Equation (6).

$$Ic \approx hfe \times ( V in / ( re \times hfe ) ) = V in / re \qquad ( 6 )$$

Thus, the bipolar transistor can determine the magnitude of a current flowing through the load resistor RL using the input voltage Vin and the resistance value of the variable resistance element MS. In other words, the bipolar transistor is an example of an element that can be used as the constant current source CP.

Here, in a case in which the magnitude of a current flowing through the load resistor RL is determined using the input voltage Vin and the resistance value of the variable resistance element MS, the resistance value of the variable resistance element MS can be used as a weight of a product operation using a neural network. In this case, the drive circuit 1, as described above, can be used as an analog circuit performing a product operation in the neural network. In a case in which the drive circuit 1 is used as an analog circuit executing a product operation in the neural network, a user can detect a change of the resistance value of the variable resistance element MS, that is, a change of the weight, by amplifying it to have a desired magnitude. This can be paraphrased that the detection resolution of changes of the resistance value of the variable resistance element MS is improved. For this reason, in this case, it becomes difficult to disturb a result of a product operation using a neural network in accordance with noise. In other words, in this case, the drive circuit 1 can inhibit an operation result acquired by a neural network from being disturbed by noise.

In the drive circuit 1 described above, a magnetoresistance effect element of a two-terminal type is used as the variable resistance element MS. However, in order to change the resistance value of the magnetoresistance effect element of the two-terminal type, in many cases, a complicated circuit needs to be designed. Thus, it is preferable that the drive circuit 1 include a magnetoresistance effect element of a three-terminal type as a variable resistance element MS.

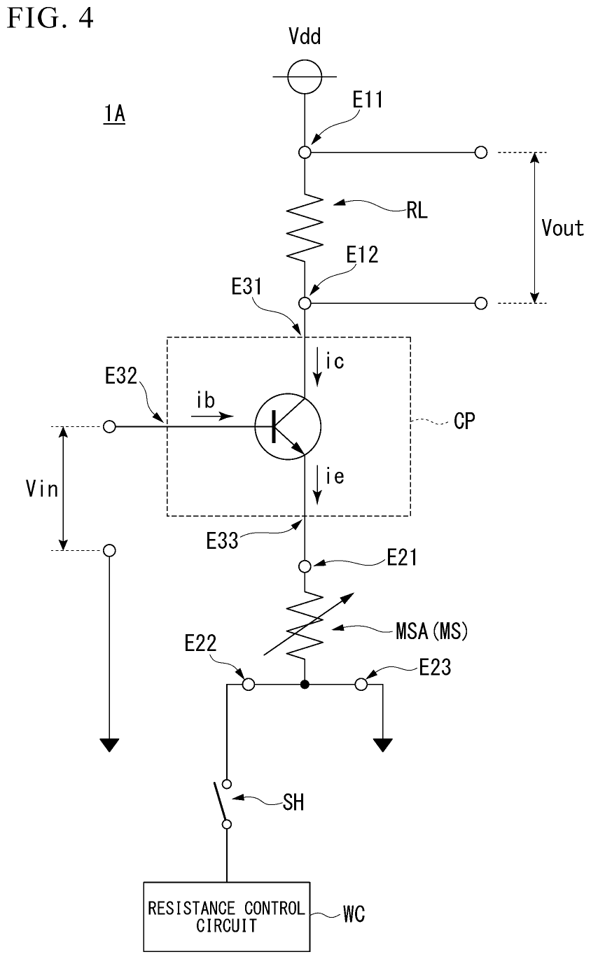

FIG. 4 is a diagram illustrating an example of the configuration of a drive circuit 1 including a variable resistance element MS of a three-terminal type. Hereinafter, for the convenience of description, in order to distinguishment from the drive circuit 1 illustrated in FIGS. 1 and 2, the drive circuit 1 illustrated in FIG. 4 will be referred to as a drive circuit 1A in description.

The drive circuit 1A includes a load resistor RL, a variable resistance element MSA, a constant current source CP, a switching element SH, and a resistance control circuit WC. In addition, the drive circuit 1A may be configured not to include any one or both of the switching element SH and the resistance control circuit WC. In the drive circuit 1A, the configuration of the load resistor RL and the configuration of the constant current source CP are similar to the configurations described in FIG. 1. For this reason, in FIG. 4, description of the configuration of the load resistor RL and the configuration of the constant current source CP will be omitted.

The variable resistance element MSA is a magnetoresistance effect element of a three-terminal type. For this reason, in this example, the variable resistance element MSA is a magnetoresistance effect element of an SOT type, a magnetoresistance effect element of a magnetic domain wall motion type, or the like. Hereinafter, as an example, a case in which the variable resistance element MSA is a magnetoresistance effect element of the magnetic domain wall motion type will be described.

The variable resistance element MSA has three terminals including a terminal E21, a terminal E22, and a terminal E23. In a case in which a voltage is applied between the terminal E22 and the terminal E23, the resistance value of the variable resistance element MSA changes in accordance with movement of a magnetic domain wall of the inside of the variable resistance element MSA. In other words, the terminal E22 and the terminal E23 are terminals used for writing a resistance value into the variable resistance element MSA. On the other hand, in a case in which a voltage is applied between the terminal E21 and the terminal E23, the drive circuit 1A outputs an output voltage Vout. In other words, the terminal E21 and the terminal E23 are terminals used in reading a resistance value of the variable resistance element MSA (for example, reading of a result of a product operation in a case in which the drive circuit 1A is used as an analog circuit executing a product operation in a neural network or the like).

The terminal E21 is connected to the terminal E33 of the constant current source CP through a transmission line. In addition, as long as the function of the drive circuit 1 is not impaired, another element, another member, another circuit, another device, and the like may be configured to be connected between the terminal E21 and the terminal E33.

The terminal E22 is connected to one of two terminals of the switching element SH through a transmission line. The other of the two terminals of the switching element SH is connected to an output terminal of the resistance control circuit WC through a transmission line. In addition, as long as the function of the drive circuit 1 is not impaired, another element, another member, another circuit, another device, and the like may be configured to be connected between the terminal E22 and the switching element SH. Furthermore, as long as the function of the drive circuit 1 is not impaired, another element, another member, another circuit, another device, and the like may be configured to be connected between the switching element SH and the resistance control circuit WC.

The terminal E23 is grounded through a transmission line. In addition, as long as the function of the drive circuit 1 is not impaired, another element, another member, another circuit, another device, and the like may be configured to be connected between the terminal E23 and the ground.

The switching element SH may be any element as long as it is an element that can perform switching of a state between the variable resistance element MS and the resistance control circuit WC between a conductive state and an insulating state in accordance with a received operation or an input signal. In FIG. 4, although the switching element SH is drawn as an element of a two-terminal type, it may be an element of a three-terminal type or an element having four terminals.

The resistance control circuit WC is a circuit that changes the resistance value of the variable resistance element MSA by applying a voltage between the terminal E22 and the terminal E23 of the variable resistance element MSA by outputting a pulse signal from an output terminal. The resistance control circuit WC may be any circuit as long as it is a circuit that can change the resistance value of the variable resistance element MSA using such a method.

As above, even in the case of a configuration including the magnetoresistance effect element of the three-terminal type, the drive circuit 1A determines the magnitude of a current flowing through the load resistor RL based on the input voltage Vin and the resistance value of the variable resistance element MSA. Even in this case, the drive circuit 1A outputs a voltage across the load resistor RL as an output voltage Vout. In accordance with this, the drive circuit 1A can improve a detection resolution of changes of the resistance value of the variable resistance element MSA according to an output voltage Vout based on the resistance value of the load resistor RL. As a result, even in this case, by using the drive circuit 1A as an analog circuit executing a product operation in a neural network, an operation result of the neural network can be inhibited from being disturbed by a noise. By including the variable resistance element MSA of the three-terminal type, the drive circuit 1A can easily change the resistance value of the variable resistance element MSA while inhibiting an operation result of the neural network from being disturbed by a noise. This allows easy design of a circuit executing an operation of the neural network and leads to inhibition of an increase of a manufacturing cost of this circuit, which is extremely preferable.

In addition, for example, in a case in which a collector current is caused to flow through the load resistor RL, the switching element SH is used for blocking a current from flowing through the resistance control circuit WC. For this reason, the switching element SH electrically insulates the variable resistance element MSA and the resistance control circuit WC from each other in a case in which the resistance control circuit WC does not change a resistance value of the variable resistance element MSA and electrically connects the variable resistance element MSA and the resistance control circuit WC to each other in a case in which this resistance value is changed. In accordance with this, the drive circuit 1A inhibits the resistance control circuit WC from being broken, and an output of the output voltage Vout with respect to an input of the input voltage Vin can be stabilized.

### Modified Example 1 of Embodiment

Hereinafter, Modified Example 1 of the embodiment will be described. In Modified Example 1 of the embodiment, a plurality of drive circuits 1 configure an array circuit 2. Hereinafter, as an example, a case in which each drive circuit 1 among the plurality of drive circuits 1 configuring the array circuit 2 is the drive circuit 1A illustrated in FIG. 4 will be described.

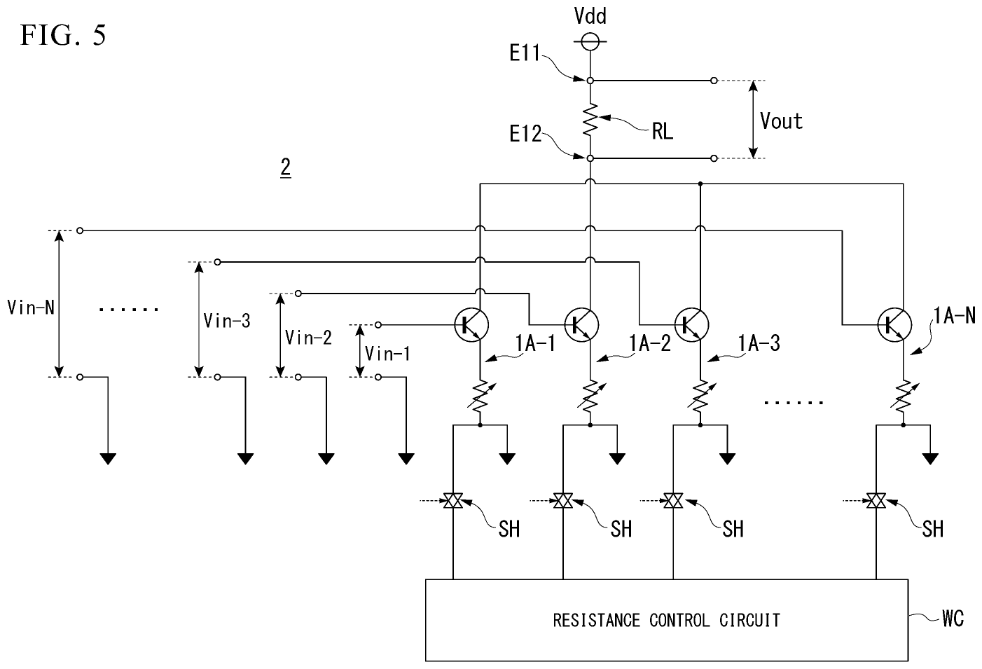

FIG. 5 is a diagram illustrating one example of the configuration of an array circuit 2. In the example illustrated in FIG. 5, the array circuit 2 includes N drive circuits 1A. N may be any number as long as it is an integer of 2 or more. In FIG. 5, these N drive circuits 1A will be distinguishably denoted respectively by a drive circuit 1A-1, a drive circuit 1A-2, . . . , and a drive circuit 1A-N.

In the array circuit 2, as illustrated in FIG. 5, the N drive circuits 1A are connected in parallel with the load resistor RL shared. In addition, in the array circuit 2, the N drive circuits 1A are connected in parallel with a resistance control circuit WC shared. In other words, the array circuit 2 includes one load resistor RL, N constant current sources CP, N variable resistance elements MSA, N switching elements SH, and one resistance control circuit WC. In addition, as long as the function of the array circuit 2 is not impaired, another element, another member, another circuit, another device, and the like may be configured to be connected between each of the N drive circuits 1A and the load resistor RL. Furthermore, as long as the function of the array circuit 2 is not impaired, another element, another member, another circuit, another device, and the like may be configured to be connected between each of the N drive circuits 1A and the resistance control circuit WC.

Here, in this specification, the array circuit 2 including one load resistor RL does not represent that the load resistor RL is composed of one resistance element. In this specification, the array circuit 2 including one load resistor RL represents that a group of one or more resistance elements functioning as a load resistor RL in which the output voltage Vout is generated at both ends is included in the array circuit 2 as one load resistor RL. In other words, in the array circuit 2, the load resistor RL is composed of one or more resistance elements.

In the example illustrated in FIG. 5, a collector terminal of the constant current source CP included in each of the N drive circuits 1A is connected to a terminal E12 of the load resistor RL through a transmission line. In this example, an input voltage Vin is independently applied to a base terminal of the constant current source CP included in each of the N drive circuits 1A. Here, in FIG. 5, an input voltage Vin applied to the base terminal of the constant current source CP of an i-th drive circuit 1A-i is denoted by an input voltage Vin-i. Here, i represents one integer among 1 to N. In addition, input voltages Vin applied to the base terminals of the constant current sources CP of some or all of the N drive circuits 1A may have either mutually-different magnitudes or the same magnitude. In other words, for example, the input voltage Vin-1 and the input voltage Vin-2 may be either voltages of mutually-different magnitudes or voltages of the same magnitude.

In addition, in the array circuit 2, the load resistor RL of the N drive circuits 1A is shared, and thus a current acquired by combining collector currents caused to flow by the constant current sources CP included in the N drive circuits 1A flows through the load resistor RL. For example, in a case in which only two drive circuits 1A including the drive circuit 1A-1 and the drive circuit 1A-2 cause collector currents to flow, a current acquired by combining a collector current caused to flow by the drive circuit 1A-1 and a collector current caused to flow by the drive circuit 1A-2 flows through the load resistor RL. In accordance with this, in a case in which the drive circuit 1A is used as an analog circuit executing a product operation as a neural network, the array circuit 2 can be caused to function as a product sum operation circuit calculating a total of results of product operations executed by N drive circuits 1A.

In addition, in the array circuit 2, the resistance control circuit WC has N output terminals. Each of these N output terminals is connected to one of the terminals E22 of the N variable resistance elements MSA without any overlapping. In accordance with this, the resistance control circuit WC can independently change a resistance value of each of N variable resistance elements MSA in the array circuit 2.

### Modified Example 2 of Embodiment

Hereinafter, Modified Example 2 of the embodiment will be described. Modified Example 2 of the embodiment is a modified example of Modified Example 1 of the embodiment. In Modified Example 1 of the embodiment, the load resistor RL is connected between the constant voltage source Vdd and the collector terminal of the constant current source CP, and thus a voltage across the load resistor RL is not an electric potential difference from a ground electric potential. In Modified Example 2 of the embodiment, since the load resistor RL is connected between the constant voltage source Vdd and the ground, an input voltage Vin and an output voltage Vout for each of the N drive circuits 1A are positive electric potentials with reference to the ground electric potential as a reference electric potential.

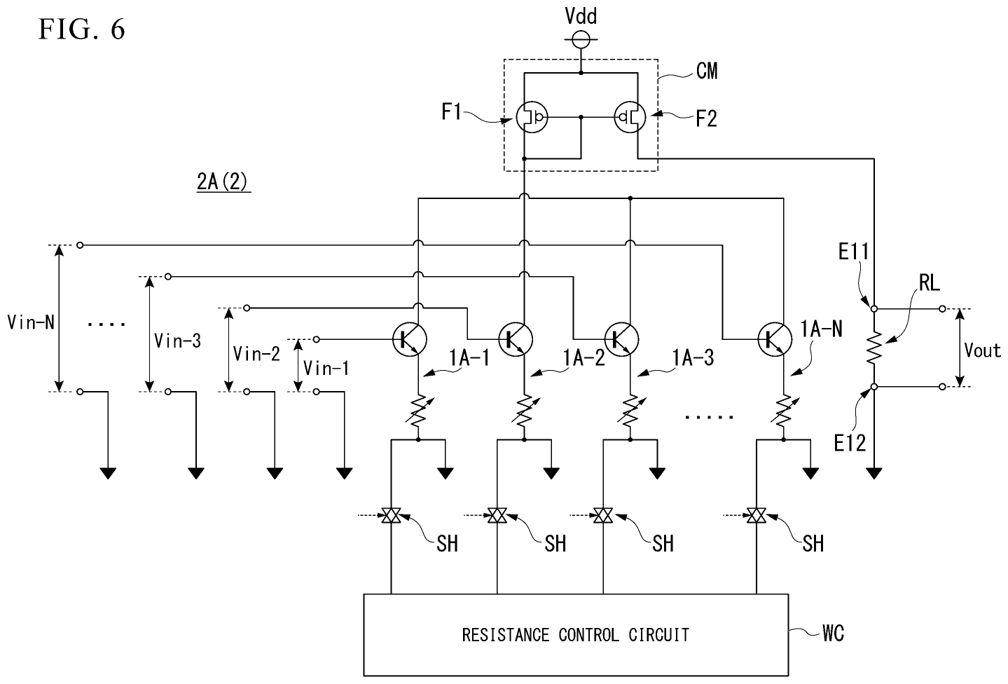

FIG. 6 is a diagram illustrating another example of the configuration of the array circuit 2. Hereinafter, for the convenience of description, the array circuit 2 illustrated in FIG. 6 will be referred to as an array circuit 2A for distinguishment from the array circuit 2 illustrated in FIG. 5.

In the array circuit 2A, as illustrated in FIG. 6, N drive circuits 1A are connected in parallel with a load resistor RL shared. Here, in the array circuit 2A, each of the N drive circuits 1A is connected to the load resistor RL through a current mirror CM. In addition, in the array circuit 2, the N drive circuits 1A are connected in parallel with a resistance control circuit WC shared. In other words, the array circuit 2 includes one load resistor RL, a current mirror CM, N constant current sources CP, N variable resistance elements MSA, N switching elements SH, and one resistance control circuit WC.

The current mirror CM includes two field effect transistors including a field effect transistor F1 and a field effect transistor F2. A drain terminal of each of the field effect transistor F1 and the field effect transistor F2 is connected to a constant voltage source Vdd through a transmission line. In addition, a source terminal of the field effect transistor F1 is connected to a collector terminal of each of the N constant current sources CP through a transmission line. Furthermore, a source terminal of the field effect transistor F2 is connected to the terminal E11 of the load resistor RL through a transmission line. In addition, the terminal E22 of the load resistor RL is grounded through a transmission line. A gate terminal of the field effect transistor F1 is connected to a gate terminal of the field effect transistor F2 and a source terminal of the field effect transistor F1 through a transmission line. In addition, as long as the function of the array circuit 2A is not impaired, another element, another member, another circuit, another device, and the like may be configured to be connected between the current mirror CM and each of the N constant current sources CP. Furthermore, as long as the function of the array circuit 2 is not impaired, another element, another member, another circuit, another device, and the like may be configured to be connected between each of the N drive circuits 1A and the resistance control circuit WC. In addition, in the array circuit 2A, connection forms other than the connection form relating to the current mirror CM are similar to the connection forms of the array circuit 2, and thus description will be omitted.

In accordance with this, the current mirror CM causes a current of the same magnitude as a magnitude of a current acquired by combining collector currents flowing through the collector terminals of the N constant current sources CP to flow through the load resistor RL. A voltage across the load resistor RL in a case in which this current flows through the load resistor RL is a positive electric potential with reference to a ground electric potential as a reference electric potential. On the other hand, in the array circuit 2A, input voltages Vin applied to the base terminals of the N constant current sources CP are positive electric potentials with reference to the ground electric potential as a reference electric potential. The reason for this is that, in the array circuit 2A, the ground electric potential of the input voltage Vin and the ground electric potential of the output voltage Vout are configured to be common. In accordance with this, a circuit designer can easily design a circuit including the array circuit 2A. In other words, the array circuit 2A can easily design the circuit including the array circuit 2A while inhibiting a result of a product operation of a neural network from being disturbed by a noise.

### Modified Example 3 of Embodiment

Hereinafter, Modified Example 3 of the embodiment will be described. Modified Example 3 of the embodiment is a modified example of Modified Example 1 of the embodiment. In Modified Example 3 of the embodiment, an array circuit 2 can increase or decrease the magnitude of a current flowing through a load resistor RL without changing the magnitude of an input voltage Vin applied to a base terminal of each of N constant current sources CP. For example, in a case in which an array circuit 2 is used as a circuit executing a product sum operation in a neural network, this corresponds to addition/subtraction of a bias constant term for a result of a product sum operation in the neural network.

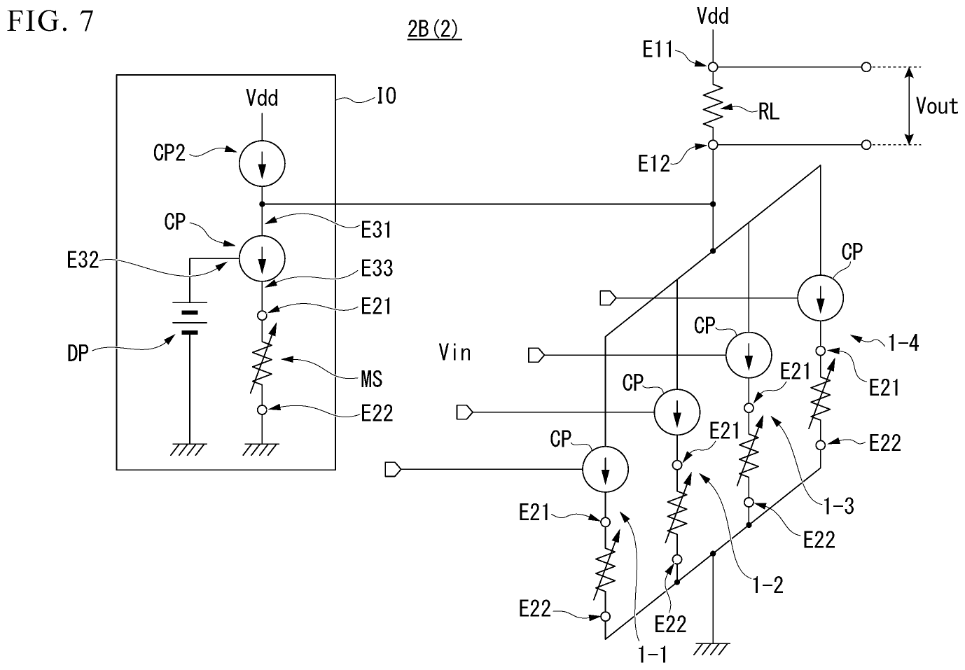

FIG. 7 is a diagram illustrating further another example of the configuration of the array circuit 2. Hereinafter, for the convenience of description, in order to distinguish the array circuit 2 illustrated in FIG. 7 from the array circuit 2 illustrated in FIG. 5, it will be referred to as an array circuit 2B in description. In the example illustrated in FIG. 7, the array circuit 2B includes four drive circuits 1 including a variable resistance element MS of a two-terminal type. In FIG. 7, these four drive circuits 1 are distinguishably denoted by a drive circuit 1-1, a drive circuit 1-2, . . . , and a drive circuit 1-N. In addition, in place of the drive circuits 1 of the two-terminal type, the array circuit 2B may be configured to include drive circuits 1A of a three-terminal type.

In the array circuit 2B, as illustrated in FIG. 7, the four drive circuits 1 are connected in parallel through a transmission line with a load resistor RL shared therebetween. For this reason, a terminal E12 of the load resistor RL is connected to a terminal E21 of each of the four drive circuits 1 through a transmission line. In addition, in the array circuit 2, a terminal E22 of each of the four variable resistance elements MS is grounded through a transmission line. The terminal E12 of the load resistor RL is connected to an output terminal of a current flow-in/out circuit IO through a transmission line. In other words, the array circuit 2B includes one load resistor RL, four constant current sources CP, four variable resistance elements MS, and a current flow-in/out circuit IO. In addition, as long as the function of the array circuit 2B is not impaired, another element, another member, another circuit, another device, and the like may be configured to be connected between the load resistor RL and the four constant current sources CP. Furthermore, as long as the function of the array circuit 2B is not impaired, another element, another member, another circuit, another device, and the like may be configured to be connected between the load resistor RL and the current flow-in/out circuit IO. In addition, as long as the function of the array circuit 2B is not impaired, another element, another member, another circuit, another device, and the like may be configured to be connected between the current flow-in/out circuit IO and the four constant current sources CP. Furthermore, as long as the function of the array circuit 2B is not impaired, another element, another member, another circuit, another device, and the like may be configured to be connected between the terminal E21 of each of the four constant current sources CP and the variable resistance element MS. In addition, as long as the function of the array circuit 2B is not impaired, another element, another member, another circuit, another device, and the like may be configured to be connected between each of the four variable resistance elements MS and the ground.

The current flow-in/out circuit IO may be any circuit as long as it is a circuit capable of at least one of causing a current to flow in the load resistor RL or causing a current to flow out from the load resistor RL. In the example illustrated in FIG. 7, the current flow-in/out circuit IO includes a constant current source CP, a constant current source CP2, a DC voltage source DP, and a variable resistance element MS.

The constant current source CP2 is a constant current source having two terminals. The constant current source CP2 causes a current of a magnitude determined in advance to flow through the constant current source CP3 in accordance with a voltage Vc supplied from the constant voltage source Vdd.

One of two terminals included in the constant current source CP2 is connected to the constant voltage source Vdd through a transmission line. In addition, the other of the two terminals included in the constant current source CP2 is connected to a terminal E31 of the constant current source CP3 through a transmission line. Furthermore, a terminal E32 of the constant current source CP3 is connected to a high potential-side terminal of the DC voltage source DP through a transmission line. In addition, a terminal E33 of the constant current source CP3 is connected to the terminal E21 of the variable resistance element MS through a transmission line. Furthermore, the terminal E22 of the variable resistance element MS is grounded through a transmission line. In addition, a low potential-side terminal of the DC voltage source DP is grounded through a transmission line. Furthermore, as long as the function of the current flow-in/out circuit IO is not impaired, another element, another member, another circuit, another device, and the like may be configured to be connected between the constant current source CP2 and the constant voltage source Vdd. In addition, as long as the function of the current flow-in/out circuit IO is not impaired, another element, another member, another circuit, another device, and the like may be configured to be connected between the constant current source CP2 and the constant current source CP. Furthermore, as long as the function of the current flow-in/out circuit IO is not impaired, another element, another member, another circuit, another device, and the like may be configured to be connected between the constant current source CP and the DC voltage source DP. In addition, as long as the function of the current flow-in/out circuit IO is not impaired, another element, another member, another circuit, another device, and the like may be configured to be connected between the constant current source CP and the variable resistance element MS in the current flow-in/out circuit IO. Furthermore, as long as the function of the current flow-in/out circuit IO is not impaired, another element, another member, another circuit, another device, and the like may be configured to be connected between the variable resistance element MS and the ground in the current flow-in/out circuit IO.

The current flow-in/out circuit IO having such a configuration causes a difference between currents caused to flow by the constant current source CP2 and the constant current source CP3 to flow to the constant current source CP of each of the four drive circuits 1. In accordance with this, the current flow-in/out circuit IO can decrease a current flowing through the load resistor RL. The magnitude of this difference changes in accordance with a change of the resistance value of the variable resistance element MS included in the current flow-in/out circuit IO. In other words, by changing this resistance value, a user can adjust a width by which the magnitude of a current flowing through the load resistor RL of the array circuit 2B is decreased.

In addition, in a case in which the current flow-in/out circuit IO does not include the constant current source CP3 and the DC voltage source DP, in other words, in a case in which the constant current source CP2 is connected between the constant voltage source Vdd and the variable resistance element MS, the current flow-in/out circuit IO increases the magnitude of the current flowing through the load resistor RL in accordance with the resistance value of the variable resistance element MS included in the current flow-in/out circuit IO. In other words, in this case, by changing this resistance value, a user can adjust a width by which the magnitude of the current flowing through the load resistor RL of the array circuit 2B is increased.

In this way, in the array circuit 2B, the current flow-in/out circuit IO can adjust the magnitude of the current flowing through the load resistor RL. As described above, in a case in which the array circuit 2B is used as a circuit executing a product sum operation in a neural network, this corresponds to addition/subtraction of a bias constant term for a result of a product sum operation in the neural network. In other words, in this case, the array circuit 2B can perform addition/subtraction of a bias constant term for a result of a product sum operation in the neural network.

The array circuits 2 illustrated in Modified Example 1 to Modified Example 3 of the embodiment described above can be used as a circuit executing a product sum operation using a neural network. In other words, by using this array circuit 2, a neuromorphic device can be configured. In other words, a neuromorphic device including this array circuit 2 can perform a product sum operation using a neural network while inhibiting an operation result from being disturbed by noise. In addition, this array circuit 2 may be configured to be able to be included in a circuit, an electronic device, a device, a member, or the like of a certain type in place of a neuromorphic device.

### Modified Example 4 of Embodiment

Hereinafter, Modified Example 4 of the embodiment will be described. In Modified Example 4 of the embodiment, the drive circuit 1 can be realized by a current mirror in place of a bipolar transistor. Hereinafter, for the convenience of description, a drive circuit 1 according to Modified Example 4 of the embodiment will be referred to as a drive circuit 1B in description.

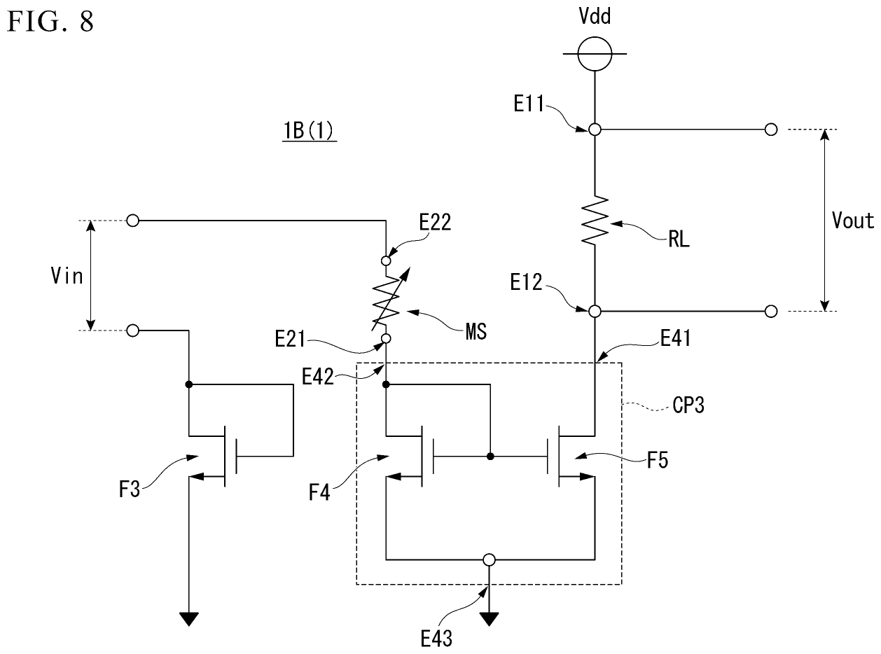

FIG. 8 is a diagram illustrating an example of the configuration of the drive circuit 1B.

The drive circuit 1B includes a load resistor RL, a variable resistance element MS, a constant current source CP3, and a field effect transistor F3. The drive circuit 1B outputs a voltage across the load resistor RL as an output voltage Vout. In addition, the drive circuit 1B may be configured not to include the field effect transistor F3. Furthermore, the configuration of each of the load resistor RL and the variable resistance element MS is similar to the configuration described in FIG. 1, and thus description thereof will be omitted.

First, a connection form of the load resistor RL, the variable resistance element MS, the constant current source CP3, and the field effect transistor F3 of the drive circuit 1B will be described.

The constant current source CP3 has three terminals including a terminal E41, a terminal E42, and a terminal E43.

A terminal E11 of the load resistor RL is connected to a constant voltage source Vdd. In other words, a voltage Vc is applied to the terminal E11 of the load resistor RL. In addition, as long as the function of the drive circuit 1B is not impaired, another element, another member, another circuit, another device, and the like may be configured to be connected between the terminal E11 and the constant voltage source Vdd.

A terminal E12 of the load resistor RL is connected to the terminal E41 of the constant current source CP3. In addition, as long as the function of the drive circuit 1B is not impaired, another element, another member, another circuit, another device, and the like may be configured to be connected between the terminal E12 and the constant current source CP3.

A transmission line used for detecting an output voltage Vout is connected to both ends of the load resistor RL. In FIG. 8, for simplification of the drawing, an external device detecting the output voltage Vout is omitted.

The terminal E42 of the constant current source CP3 is connected to a terminal E21 of the variable resistance element MS through a transmission line. In addition, as long as the function of the drive circuit 1B is not impaired, another element, another member, another circuit, another device, and the like may be configured to be connected between the terminal E42 and the variable resistance element MS.

The terminal E43 of the constant current source CP3 is grounded through a transmission line. In addition, as long as the function of the drive circuit 1B is not impaired, another element, another member, another circuit, another device, and the like may be configured to be connected between the terminal E43 and the ground.

A terminal E22 of the variable resistance element MS is a terminal to which the input voltage Vin is input. For this reason, an external circuit, an external device, and the like capable of supplying the input voltage Vin to the terminal E22 are connected to the terminal E22. In FIG. 8, for simplification of the drawing, such an external circuit, such an external device, and the like are omitted. In addition, as long as the function of the drive circuit 1B is not impaired, another element, another member, another circuit, another device, and the like may be configured to be connected between the terminal E22 and the external circuit, the external device, and the like.

An external circuit, an external device, and the like are connected to a drain terminal of the field effect transistor F3 through a transmission line. Such an external circuit, such an external device, and the like are an external circuit, an external device, and the like connected to the terminal E22 of the variable resistance element MS. This drain terminal is a terminal that applies a reference electric potential of the input voltage Vin. In other words, in Modified Example 4 of the embodiment, the input voltage Vin is an electric potential difference from the electric potential of this drain terminal. In addition, as long as the function of the drive circuit 1B is not impaired, another element, another member, another circuit, another device, and the like may be configured to be connected between this drain terminal and the external circuit, the external device, and the like.

A gate terminal of the field effect transistor F3 is connected to a drain terminal of the field effect transistor F3 through a transmission line. In other words, the field effect transistor F3 is a bias circuit. In addition, as long as the function of the drive circuit 1B is not impaired, another element, another member, another circuit, another device, and the like may be configured to be connected between this gate terminal and this drain terminal.

A source terminal of the field effect transistor F3 is grounded through a transmission line. In addition, as long as the function of the drive circuit 1B is not impaired, another element, another member, another circuit, another device, and the like may be configured to be connected between this source terminal and the ground.

Here, the constant current source CP3 is a current mirror including two field effect transistors including a field effect transistor F4 and a field effect transistor F5.

A drain terminal of the field effect transistor F4 is connected to each of a terminal E42 of the constant current source CP3, a gate terminal of the field effect transistor F4, and a gate terminal of the field effect transistor F5 through a transmission line. In addition, as long as the function of the drive circuit 1B is not impaired, another element, another member, another circuit, another device, and the like may be configured to be connected between this drain terminal and the terminal E42. Furthermore, as long as the function of the drive circuit 1B is not impaired, another element, another member, another circuit, another device, and the like may be configured to be connected between this drain terminal and each of these two gate terminals.

A source terminal of the field effect transistor F4 is connected to each of the terminal E43 of the constant current source CP3 and the source terminal of the field effect transistor F5 through a transmission line. In addition, as long as the function of the drive circuit 1B is not impaired, another element, another member, another circuit, another device, and the like may be configured to be connected between each of these two source terminals and the terminal E42. Furthermore, as long as the function of the drive circuit 1B is not impaired, another element, another member, another circuit, another device, and the like may be configured to be connected between these two source terminals.

A drain terminal of the field effect transistor F5 is connected to the terminal E41 of the constant current source CP3 through a transmission line. In addition, as long as the function of the drive circuit 1B is not impaired, another element, another member, another circuit, another device, and the like may be configured to be connected between this drain terminal and the terminal E41.

Similar to each of the drive circuit 1 and the drive circuit 1A, the drive circuit 1B having the configuration as described above determines the magnitude of a current flowing through the load resistor RL based on the input voltage Vin and the resistance value of the variable resistance element MS as well. In accordance with this, the drive circuit 1B can improve the resolution for changes of the resistance value of the variable resistance element MS. As a result, for example, in a case in which the drive circuit 1B is used as an analog circuit executing a product operation in a neural network, a user can detect a resistance value of the variable resistance element MS, that is, a change of the weight, by amplifying it to have a desired magnitude. This can be paraphrased that the detection resolution of changes of the resistance value of the variable resistance element MS is improved. For this reason, in this case, it becomes difficult for a result of a product operation using a neural network to be disturbed by noise. In other words, in this case, the drive circuit 1B can inhibit an operation result of a neural network from being disturbed by noise.

In addition, also in the drive circuit 1B, the variable resistance element MS may be substituted with a magnetoresistance effect element of the three-terminal type.

### <Method for Configuring Drive Circuit>

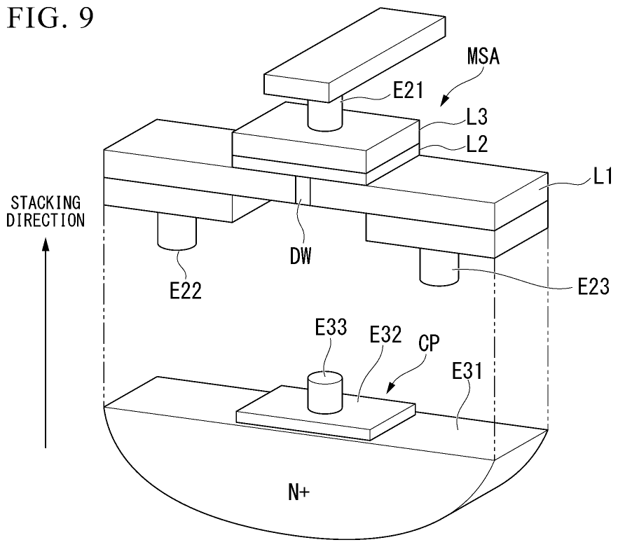

Hereinafter, a method for configuring the drive circuit 1 described above will be described. The constant current source CP and the variable resistance element MS of the drive circuit 1 may be stacked as an integrated circuit on a substrate. Hereinafter, as an example, a case in which the constant current source CP and the variable resistance element MSA of the three-terminal type of the drive circuit 1A are stacked as an integrated circuit on a substrate. FIG. 9 is an image view illustrating an example of a view in which a constant current source CP and a variable resistance element MSA of the three-terminal type of the drive circuit 1A are stacked on a substrate using a top pin structure as an integrated circuit. In FIG. 9, for simplification of the drawing, the substrate is omitted.

In the example illustrated in FIG. 9, when the constant current source CP and the variable resistance element MSA are seen in a stacking direction in which the constant current source CP and the variable resistance element MSA are stacked, the constant current source CP and the variable resistance element MSA almost overlap each other in a top pin structure. In other words, in this example, on a bottom face of the variable resistance element MSA arranged in the top pin structure, in this case, the constant current source CP that is a bipolar transistor is arranged such that the constant current source CP and the variable resistance element MSA overlap each other. In accordance with this, an increase in the size of the integrated circuit of the drive circuit 1 can be suppressed. In FIG. 9, for simplification of the drawing, a transmission line connected to each of a terminal E21, a terminal E22, and a terminal E23 of the variable resistance element MSA and a terminal E31, a terminal E32, and a terminal E33 of the constant current source CP and the like are omitted. In addition, a magnetic domain wall DW illustrated in FIG. 9 illustrates an example of a magnetic domain wall of the variable resistance element MSA that is a magnetoresistance effect element of the magnetic domain wall motion type.

Here, a layer L1 included in the variable resistance element MS illustrates an example of a magnetic domain wall motion layer in a magnetoresistance effect element of the magnetic domain wall motion type. In addition, a layer L2 included in the variable resistance element MS illustrates an example of a non-magnetic layer in this magnetoresistance effect element. A layer L3 included in the variable resistance element MS illustrates an example of a magnetization fixed layer in which a direction of magnetization is fixed among layers of this magnetoresistance effect element.

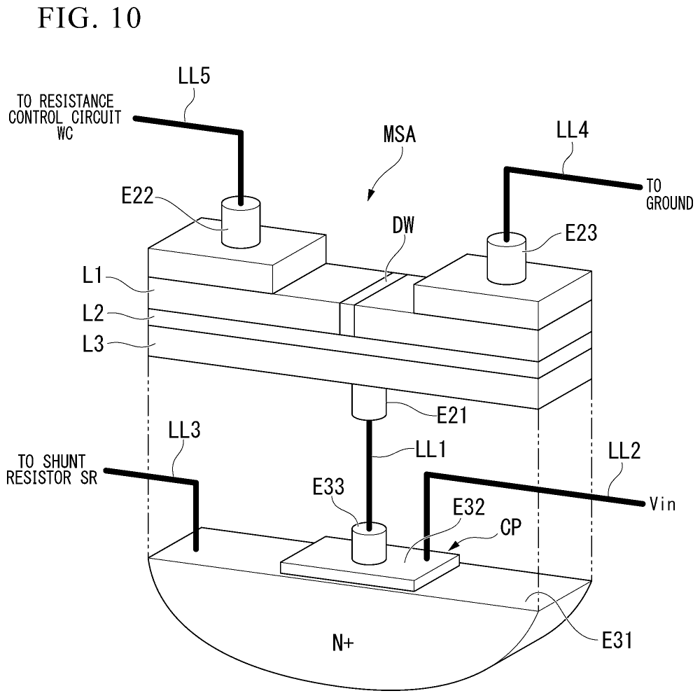

In addition, stacking of the constant current source CP and the variable resistance element MS on the substrate may be performed in a bottom-top pin structure. In this case, as illustrated in FIG. 10, the constant current source CP and the variable resistance element MSA of the drive circuit 1 are stacked on the substrate. FIG. 10 is an image view illustrating an example of a view in which a constant current source CP and a variable resistance element MSA of the three-terminal type of the drive circuit 1A are stacked on a substrate using a bottom-top pin structure as an integrated circuit.

In the example illustrated in FIG. 10, when the constant current source CP and the variable resistance element MSA are seen in a stacking direction in which the constant current source CP and the variable resistance element MSA are stacked, the constant current source CP and the variable resistance element MSA almost overlap each other in a bottom-top pin structure. In other words, in this example, on a bottom face of the variable resistance element MSA arranged in the bottom-top pin structure, in this case, the constant current source CP that is a bipolar transistor is arranged such that the constant current source CP and the variable resistance element MSA overlap each other. Also in this case, an increase in the size of the integrated circuit of the drive circuit 1 can be suppressed. A transmission line LL1 illustrated in FIG. 10 is an example of a transmission line connecting the terminal E33 of the constant current source CP and the terminal E21 of the variable resistance element MS. In addition, a transmission line LL2 illustrated in FIG. 10 is an example of a transmission line connected to an external device inputting an input voltage Vin to the constant current source CP. Furthermore, a transmission line LL3 illustrated in FIG. 10 is an example of a transmission line connecting the terminal E31 of the constant current source CP and the load resistor RL. In addition, a transmission line LL4 illustrated in FIG. 10 is an example of a transmission line connecting the terminal E23 of the variable resistance element MS and the ground. Furthermore, a transmission line LL5 illustrated in FIG. 10 is an example of a transmission line connecting the constant current source CP and the resistance control circuit WC.

As above, the drive circuit according to an embodiment (in the example presented above, the drive circuit 1, the drive circuit 1A, and the drive circuit 1B) includes a load resistor (in the example described above, the load resistor RL), a variable resistance element (in the example described above, the variable resistance element MS) that has at least a first terminal (in the example described above, the terminal E21 of the variable resistance element MS) and a second terminal (in the example described above, the terminal E22 of the variable resistance element MS) and is capable of changing the resistance value based on the magnetoresistance effect, and a constant current source (in the example described above, the constant current source CP) that determines the magnitude of a current flowing through the load resistor based on an input voltage (the input voltage Vin in the example described above) and the resistance value of the variable resistance element and outputs a voltage across the load resistor (in the example described above, a voltage between the terminal E11 of the load resistor RL and the terminal E12 of the load resistor RL) as an output voltage (in the example described above, the output voltage Vout). In accordance with this, the drive circuit can improve the resolution for changes of the resistance value of the variable resistance element.

Furthermore, in the drive circuit, the load resistor configured to be able to select a resistance value may be used.

In addition, in the drive circuit, the variable resistance element configured to have a third terminal (the terminal E23 of the variable resistance element MS in the example described above) in addition to the first terminal and the second terminal may be used.

Furthermore, in the drive circuit, the variable resistance element having a configuration of a magnetic domain wall motion type may be used.

In addition, in the drive circuit, a configuration in which a resistance value of the variable resistance element changes in a case in which a voltage is applied between the second terminal and the third terminal, and the drive circuit further includes a resistance control circuit (in the example described above, the resistance control circuit WC) applying a voltage between the second terminal and the third terminal may be used.

Furthermore, in the drive circuit, a configuration in which a switching element (in the example described above, the switching element SH) is connected between at least one of the second terminal and the third terminal and the resistance control circuit may be used.

In addition, in the drive circuit, a configuration in which one of two terminals included in the load resistor is connected to a constant voltage source (in the example described above, the constant voltage source Vdd), and a constant current source is a bipolar transistor including a base terminal to which an input voltage is applied, a collector terminal connected to the other of the two terminals included in the load resistor, and an emitter terminal connected to the first terminal of the variable resistance element may be used.

Furthermore, in the drive circuit, a configuration in which the variable resistance element and the bipolar transistor are stacked as an integrated circuit may be used.

In addition, in an array circuit according to an embodiment (in the example described above, the array circuit 2, the array circuit 2A, and the array circuit 2B) may use a configuration in which a variable resistance element and a bipolar transistor are stacked as an integrated circuit.

Furthermore, in the array circuit, a configuration in which a load resistor shared by a plurality of the drive circuits and a constant current source included in each of the plurality of the drive circuits are connected through a current mirror (in the example described above, the current mirror CM), and a ground electric potential of the input voltage and a ground electric potential of the output voltage are configured to be common may be used.

In addition, in the array circuit, a configuration in which a current flow-in/out circuit (in the example described above, the current flow-in/out circuit IO) that can perform at least one of causing a current to flow in the load resistor and causing a current to flow out from the load resistor is connected may be used.

In addition, in the array circuit, a configuration in which a current flow-in/out circuit (in the example described above, the current flow-in/out circuit IO) that can perform at least one of causing a current to flow in the load resistor and causing a current to flow out from the load resistor is connected may be used.

### REFERENCE SIGNS LIST

1, 1-1, 1-2, 1A, 1A-1, 1A-2, 1A-i, 1A-N, 1B, 1-N Drive circuit
2, 2A, 2B Array circuit
CM Current mirror
CP, CP2, CP3 Constant current source
DP DC voltage source
F1, F2, F3, F4, F5 Field effect transistor
IO Current flow-in/out circuit
MS, MSA Variable resistance element
RL Load resistor
SH Switching element
Vdd Constant voltage source
WC Resistance control circuit

1. A drive circuit comprising:
a load resistor;
a variable resistance element configured to have at least a first terminal and a second terminal and be capable of changing a resistance value based on a magnetoresistance effect; and
a constant current source configured to determine a magnitude of a current flowing through the load resistor based on an input voltage and a resistance value of the variable resistance element,
wherein a voltage across the load resistor is output as an output voltage.

2. The drive circuit according to claim 1, wherein the resistance value of the load resistor is able to be selected.

3. The drive circuit according to claim 1, wherein the variable resistance element has a third terminal in addition to the first terminal and the second terminal.

4. The drive circuit according to claim 3, wherein the variable resistance element is a magnetic domain wall motion type.

5. The drive circuit according to claim 4,
wherein the resistance value of the variable resistance element changes in a case in which a voltage is applied between the second terminal and the third terminal, and
wherein the drive circuit further includes a resistance control circuit applying a voltage between the second terminal and the third terminal.

6. The drive circuit according to claim 5, wherein a switching element is connected between at least one of the second terminal and the third terminal and the resistance control circuit.

7. The drive circuit according to claim 1,
wherein one of two terminals included in the load resistor is connected to a constant voltage source, and
wherein the constant current source is a bipolar transistor including a base terminal to which the input voltage is applied, a collector terminal connected to the other of the two terminals included in the load resistor, and an emitter terminal connected to the first terminal of the variable resistance element.

8. The drive circuit according to claim 7, wherein the variable resistance element and the bipolar transistor are stacked as an integrated circuit.

9. An array circuit comprising:
a plurality of the drive circuits according to claim 1,
wherein the plurality of the drive circuits share the load resistor and are connected in parallel.

10. The array circuit according to claim 9,
wherein the load resistor shared in the plurality of the drive circuits and the constant current source of each of the plurality of the drive circuits are connected to each other through a current mirror, and
wherein a ground electric potential of the input voltage and a ground electric potential of the output voltage are configured to be common.

11. The array circuit according to claim 9, wherein a current flow-in/out circuit that is able to perform at least one of causing a current to flow in the load resistor and causing a current to flow out from the load resistor is connected.

12. A neuromorphic device comprising the array circuit according to claim 9.
